(19) United States
(12) Patent Application Publication
(10) Pub. No.: US 2006/0098512 A1
(43) Pub. Date: May 11, 2006

(54) Electronic apparatus

(75) Inventors: Tsutomu Tanaka, Tokyo (JP); Kunihiko Aoto, Tokyo (JP); Kiyoko Maruyama, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: KABUSHIKI KAISHA TOSHIBA, Tokyo (JP)

(21) Appl. No.: 11/266,781

(22) Filed: Nov. 4, 2005

(30) Foreign Application Priority Data
Nov. 9, 2004 (JP) 2004-324884

(51) Int. Cl. G11C 5/14

(52) U.S. Cl. 365/229

(57) ABSTRACT

There is provided an electronic apparatus comprising a battery holder, a detector detecting a battery, a non-volatile memory storing a program for initialization, a volatile memory, a first power supply for the non-volatile memory, a second power supply for the volatile memory, a power switch, a power supply controller activating the first power supply and the second power supply after the battery is detected or after the power switch is turned on, and a management circuit sending the program from the non-volatile memory to the volatile memory if the first and the second power supplies are activated and before the program is fully sent to the volatile memory, causing the power supply controller to deactivate the first power supply after sending the program, and causing the program in the volatile memory to run after the power switch is turned on.

### CROSS REFERENCE TO RELATED APPLICATIONS

This application is based upon and claims the benefit of priority from the prior Japanese Patent Application No. 2004-324884 filed on Nov. 9, 2004;

the entire contents of which are incorporated herein by reference.

### FIELD OF THE INVENTION

The present invention relates to an electronic apparatus to be supplied with power by a battery.

### DESCRIPTION OF THE BACKGROUND

There is known a portable electronic apparatus using an external master read-only memory (ROM) attached thereto, in which a boot program, an operating system program and application programs are stored. Those programs are sent to the electronic apparatus to run, and this conventional electronic apparatus and its booting method are disclosed in Japanese Patent Publication (Kokai), H11-175414.

This electronic apparatus uses a battery and has an internal random access memory (RAM) to which the boot program is sent from the master ROM and written while the battery is being charged. After the boot program is written to the RAM and the electronic apparatus is switched off, the RAM keeps supplied with power so that the written program is not broken. After being switched on, the electronic apparatus boots itself with the boot program read out of the RAM to get ready soon.

An external master ROM enables the electronic apparatus to be equipped with a smaller number of non-volatile memories for boot programs, operating system programs and application programs, and to load those programs of most up-to-date versions.

There is known a data processing apparatus having a first power supply supplying power to a ROM thereof only while the apparatus is being switched on, and a second power supply always supplying power to a high-speed memory device, even while the apparatus is being switched off. This conventional data processing apparatus and its booting method are disclosed in Japanese Patent Publication (Kokai), H11-184703.

This data processing apparatus copies its BIOS codes stored in the ROM to the high-speed memory device, and reads the BIOS codes out of the high-speed memory device to boot itself after the first power supply is deactivated and then activated. The high-speed memory device enables the data processing apparatus to boot itself and get ready much sooner than the ROM does.

There is known a mobile phone capable of limiting kinds of call requests after its battery discharges to a certain extent. This conventional mobile phone and its method of limiting kinds of call requests are disclosed in Japanese Patent Publication (Kokai), 2001-8267.

This mobile phone is automatically switched off after the battery discharges below a certain value of voltage, and is automatically switched on after an emergency button thereof is pressed to request an emergency call. This method of battery saving enables the mobile phone to request an emergency call even after the battery discharges.

The portable electronic apparatus stated above may break the program written to the RAM in a case where the power supplied to the RAM fails for a short time or its voltage drops, and may fail to work correctly after being switched on. There is another concern that the battery gradually discharges after shipment and the disclosed method of this electronic apparatus includes no remedy for this concern.

The data processing apparatus stated above may break the BIOS codes copied into the high-speed memory device in a case where the second power supply fails for a short time or its voltage drops, and may fail to work correctly after the first power supply is activated. There is another concern that the battery gradually discharges after shipment and the disclosed method of this data processing apparatus includes no remedy for this concern.

The mobile phone stated above may have a problem that it does not recover the data broken after the mobile phone is automatically switched off

### SUMMARY OF THE INVENTION

Accordingly, an advantage of the present invention is to provide an electronic apparatus capable of storing a program in a volatile working memory before starting to work while saving power consumption.

To achieve the above advantage, one aspect of the present invention is to provide an electronic apparatus comprising a battery holder, a detector for detecting a battery placed in the battery holder, a non-volatile memory for storing a program for initialization, a volatile memory, a first power supply for supplying the non-volatile memory with power from the battery placed in the battery holder, a second power supply for supplying the volatile memory with power from the battery placed in the battery holder, a power switch for causing the first power supply and the second power supply to be activated, a power supply controller for activating the first power supply and the second power supply after the detector detects the battery, and for activating the first power supply and the second power supply after the power switch is turned on, and a management circuit for sending the program from the non-volatile memory to the volatile memory after the first power supply and the second power supply are activated and before the program is fully sent to the volatile memory, for causing the power supply controller to deactivate the first power supply after sending the program and before the power switch is turned on, and for causing the program in the volatile memory to run after the power switch is turned on.

### BRIEF DESCRIPTION OF THE DRAWINGS

FIG. 1 is a block diagram of an electronic apparatus of the first embodiment of the present invention.

FIG. 2 is a timing chart of a processing sequence of the first embodiment.

FIG. 3 is a flow chart of processing of the power supply controller of the first embodiment.

FIG. 4 is a flow chart of processing of the management circuit of the first embodiment.

FIG. 5 is a block diagram of an electronic apparatus of the second embodiment of the present invention.

FIG. 6 is a timing chart of a first processing sequence of the second embodiment.

FIG. 7 is a timing chart of a second processing sequence of the second embodiment.

FIG. 8 is a timing chart of a third processing sequence of the second embodiment.

FIG. 9 is a flow chart of processing of the power supply controller of the second embodiment.

FIG. 10 is a block diagram of an electronic apparatus of the third embodiment of the present invention.

FIG. 11 is a timing chart of a processing sequence of the third embodiment.

FIG. 12 is a flow chart of processing of the power supply controller of the third embodiment.

FIG. 13 is a block diagram of an electronic apparatus of the fourth embodiment of the present invention.

FIG. 14 is a timing chart of a processing sequence of the fourth embodiment.

FIG. 15 is a block diagram of an electronic apparatus of the fifth embodiment.

FIG. 16 is a first flow chart of processing of the electronic apparatus of the fifth embodiment.

FIG. 17 is a second flow chart of processing of the electronic apparatus of the fifth embodiment.

FIG. 18 is a third flow chart of processing of the electronic apparatus of the fifth embodiment.

### DETAILED DESCRIPTION OF THE INVENTION

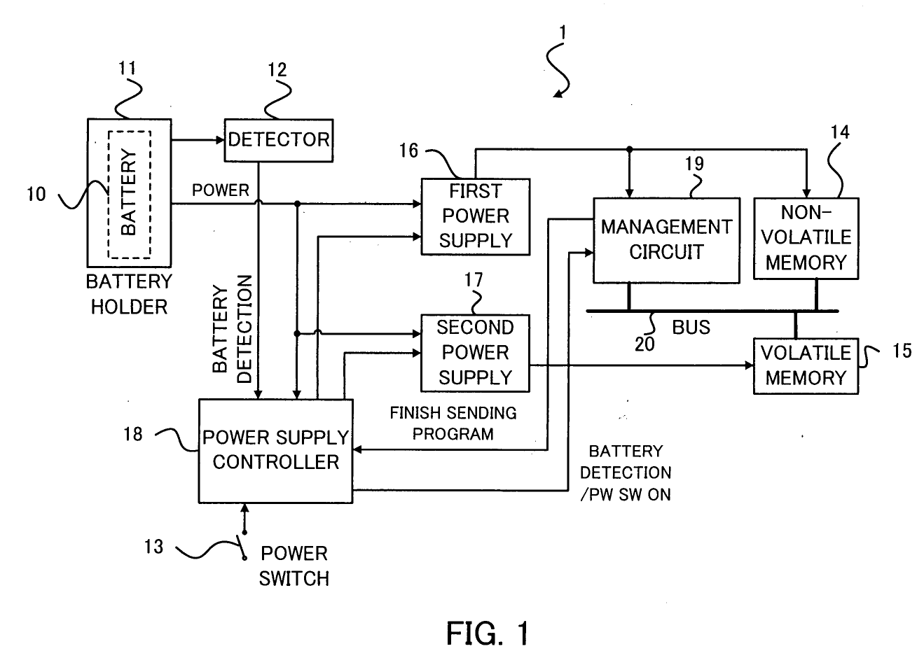

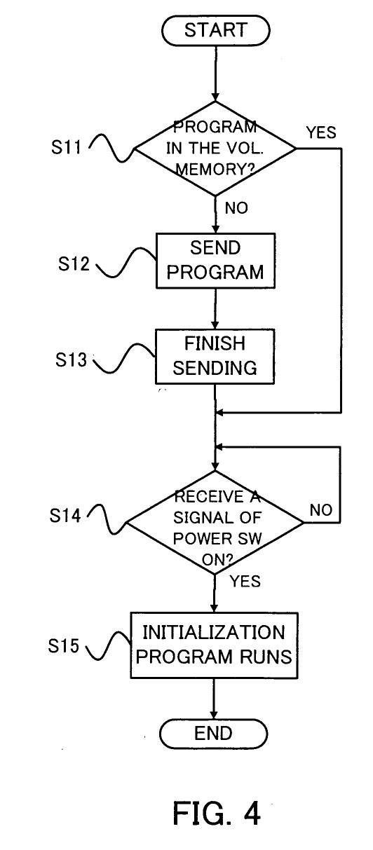

A first embodiment of the present invention will be described with reference to FIG. 1 and FIG. 4. FIG. 1 is a block diagram of an electronic apparatus 1 of the first embodiment, e.g. a mobile phone. The electronic apparatus 1 may be supplied with power by a battery 10.

The electronic apparatus 1 has a battery holder 11. The battery 10 may be placed in the battery holder 11 and may be removed from the battery holder 11. The battery holder 11 has a spring-like contact configured to contact an electrode of the battery 10.

The electronic apparatus 1 has a detector 12 for detecting the battery 10 placed in the battery holder 11. The detector 12 may detect the battery 10 by a mechanical means, e.g., a switch fitted in the battery holder 11 in a manner to be pushed after the battery 10 is placed in the battery holder 11.

The electronic apparatus 1 has a non-volatile memory 14 for storing a program for initialization like a boot program, an operating system program or an application program, to make the electronic apparatus 1 ready to work.

The electronic apparatus 1 has a volatile memory 15 and used as a working memory, i.e., the program is fully therein while running. The program is sent from the non-volatile memory 14 and written to the volatile memory 15 before the electronic apparatus 1 starts working.

The electronic apparatus 1 has a first power supply 16 for supplying the non-volatile memory 14 with power from the battery 10 placed in the battery holder 11.

The electronic apparatus 1 has a second power supply 17 for supplying the volatile memory 15 with power from the battery 10 placed in the battery holder 11.

The power of the battery 10 is thus divided into two lines, the one is via the first power supply 16 to the non-volatile memory 14, and the other is via the second power supply to the volatile memory 15. The first power supply 16 may supply other portions of the electronic apparatus 1 with power. The second power supply 17 may supply other portions of the electronic apparatus 1 with power.

The electronic apparatus 1 has a power switch 13 for causing the first power supply and the second power supply to be activated. The power switch 13 may be a manual switch or an automatic switch with a timer (not shown). In the latter case, the power switch 13 is turned on or off after a preset time comes, or turned off after a preset period of time passes after a last operation is done on the electronic apparatus 1.

In a case where the electronic apparatus 1 is configured in a first housing (not shown) and a second housing (not shown) connected to each other and configured to open and close to each other, the power switch 13 may be turned on after the first housing and the second housing open to each other.

The electronic apparatus 1 has a power supply controller 18 for activating or deactivating the first power supply 16 or the second power supply 17. The power supply controller 18 is connected to the battery holder 11 and is supplied with power directly by the battery 10 placed in the battery holder 11.

The power supply controller 18 is connected to the detector 12, being aware of the detection of the battery 10. The power supply controller 18 is connected to the power switch 13, being aware if the power switch 13 is turned on or off. The power supply controller 18 activates the first power supply 16 and the second power supply 17 after the detector 12 detects the battery 10, or after the power switch 13 is turned on.

The electronic apparatus 1 has a management circuit 19 for a control of the non-volatile memory 14 and the volatile memory 15. The management circuit 19 sends the program from the non-volatile memory 14 to the volatile memory 15, i.e., reads the program out of the non-volatile memory 14 and writes the program to the volatile memory 15, after the first power supply 16 and the second power supply 17 are activated and before the program is fully sent to the volatile memory 15.

The management circuit 19 sends a signal to the power supply controller 18 indicating that the management circuit 19 finishes sending the program from the non-volatile memory 14 to the volatile memory 15. The power supply controller 18 then deactivates the first power supply 16.

The management circuit 19 is supplied with power by the first power supply 16. The power supply controller 18 sends a signal to the management circuit 19 indicating that the battery 10 is detected. The power supply controller 18 sends a signal to the management circuit 19 indicating that the power switch 13 is turned on.

The management circuit 19 distinguishes a case where the detection of the battery 10 causes the management circuit 19 to be activated from another case where the power switch 13 having been turned on causes the management circuit 19 to be activated. In the latter case, the management circuit 19 causes the program for initialization in the volatile memory 15 to run.

The non-volatile memory 14, the volatile memory 15 and the management circuit 19 are connected one another by way of a bus 20. The management circuit 19 includes a central processing unit (CPU), an input and output interface (I/O) and so forth, and may control portions of the electronic apparatus 1 other than the non-volatile memory 14 and the volatile memory 15.

The non-volatile memory 14 may store an application program, a database like a directory and so forth in addition to the program for initialization. The non-volatile memory 14 is, e.g., a NAND flash memory. The volatile memory 15 is a working memory and is, e.g., a synchronous dynamic random access memory (SDRAM) capable of working faster than non-volatile memories.

Sending the program for initialization, other programs or data from the non-volatile memory 14 to the volatile memory 15 may require a certain period of time, e.g., nearly ten seconds in a case of a mobile phone. An aspect of the present invention is completing this process before the power switch 13 is turned on to eliminate a need to wait for such a long time after the power switch 13 is turned on.

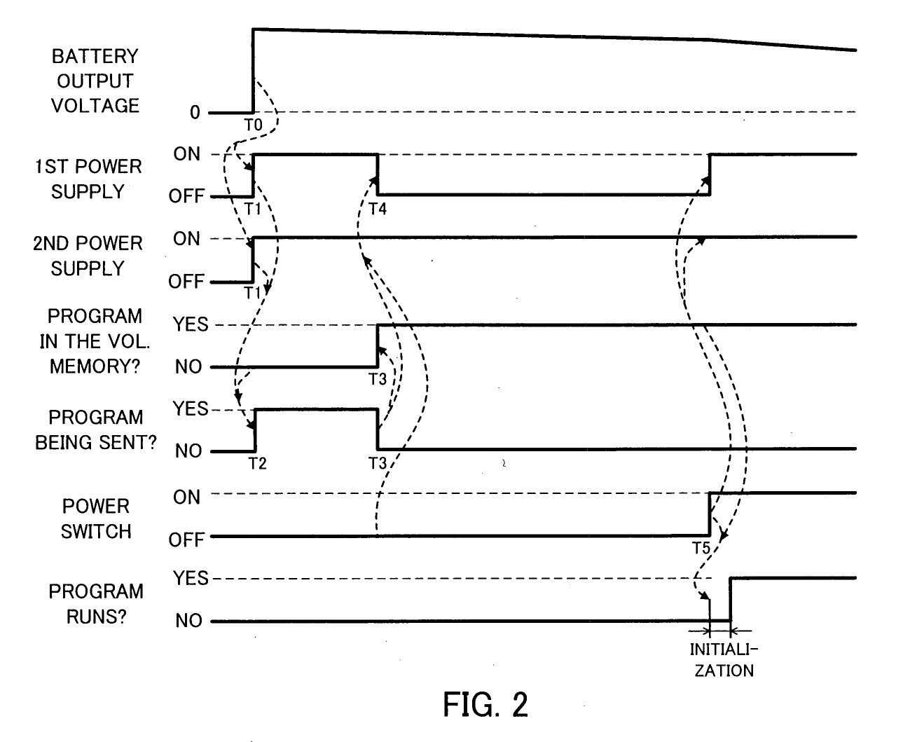

A processing sequence of the first embodiment will be described with reference to a timing chart shown in FIG. 2. The timing chart includes seven state transitions of each portion of the electronic apparatus 1 on a common, horizontally drawn time axis, after the battery 10 is placed in the battery holder 11. A curved dotted line with an arrow shows a relation of cause and effect between events included in this timing chart, and in other timing charts referred to in following embodiments as well.

A first state transition drawn at the top of FIG. 2 is a waveform of the output voltage of the battery 10. The waveform may actually fluctuate by load fluctuations in a case where the first power supply 16 or the second power supply 17 is activated or deactivated. Such fluctuations, however, are not shown in FIG. 2 for simplicity.

A second state transition shows whether the first power supply 16 is activated or deactivated. A third state transition shows whether the second power supply 17 is activated or deactivated.

A fourth state transition shows whether the program for initialization is fully in the volatile memory 15 or not. A fifth state transition shows whether the program is being sent or not from the non-volatile memory 14 to the volatile memory 15.

A sixth state transition shows whether the power switch 13 is turned on or off. A seventh state transition shows whether the program is running or not, i.e., whether the electronic apparatus 1 is working or not.

In the first state transition, the battery 10 is placed in the battery holder 11 at a time T0, e.g., a time of shipment of the electronic apparatus 1. The output voltage rises to a certain value at T0.

The detector 12 detects the battery 10 at T0, and the power supply controller 18 is aware of the detection. The power supply controller 18 activates the first power supply 16 and the second power supply 17 at a time T1 after T0. The management circuit 19 is activated after the first power supply 16 is activated. The power supply controller 18 sends a signal to the management circuit 19 indicating the detection at T1, as shown in FIG. 1, so that the management circuit 19 is aware that the detection causes the management circuit 19 to be activated.

After T1, the first power supply 16 and the second power supply 17 are activated and the program for initialization is not in the volatile memory 15, as it has not been supplied with power before T1. The management circuit 19 then starts to send the program from the non-volatile memory 14 to the volatile memory 15 at a time T2 after T1.

At a time T3, a certain period of time after T2, the management circuit 19 finishes sending the program. The program is fully in the volatile memory 15 and is ready to run after T3. The management circuit 19 sends a signal to the power supply controller 18 indicating that the management circuit 19 finishes sending the program as shown in FIG. 1. The power supply controller 18 then deactivates the first power supply 16 at a time T4 while the power switch 13 is turned off and after T3. The second power supply 17 keeps activated and keeps supplying power to the volatile memory 15 after T4.

At a time T5 after T4, the power switch 13 is turned on, e.g., after the electronic apparatus 1 is purchased. The power supply controller 18 is aware that the power switch 13 is turned on, and activates the first power supply 16 and the second power supply 17. The power supply controller 18 actually keeps the second power supply 17 activated. The power supply controller 18 sends a signal to the management circuit 19 indicating that the power switch 13 is turned on, as shown in FIG. 1, so that the management circuit 19 is aware that the power switch 13 having been turned on causes the management circuit 19 to be activated.

After T5, the power switch 13 has been turned on and the program for initialization is fully in the volatile memory 15. The management circuit 19 causes the program to run, i.e., to initialize the electronic apparatus 1 and get it ready to work.

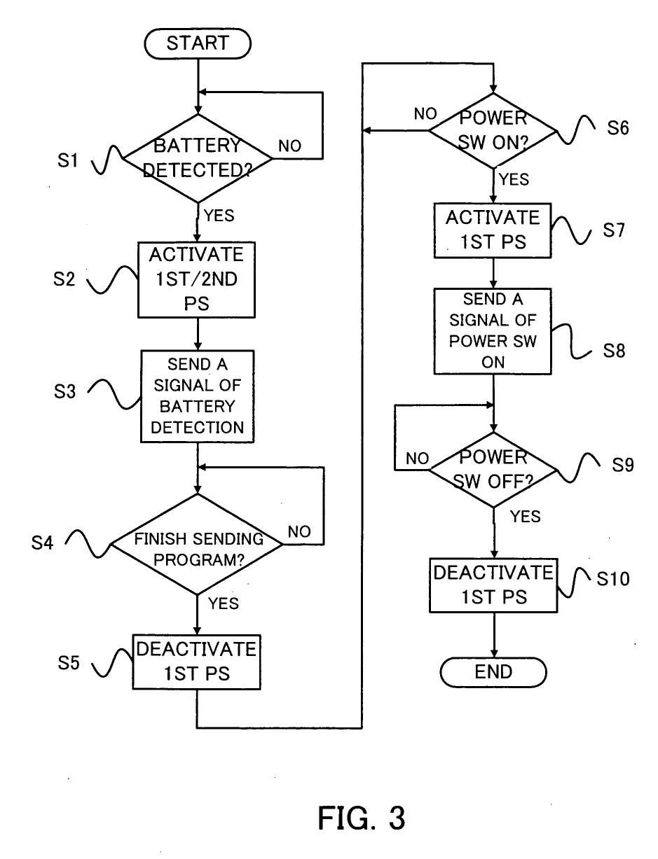

FIG. 3 is a flow chart of processing of the power supply controller 18 of the first embodiment. The power supply controller 18 starts processing (“START”) after the battery 10 is placed in the battery holder 11. The power supply controller 18 waits for the detector 11 to detect the battery 10 (“NO” of step “S1”). After the detection (“YES” of step “S1”), the power supply controller 18 activates the first power supply 16 and the second power supply 17 (step “S2”), and sends a signal to the management circuit 19 indicating the battery detection (step “S3”).

The power supply controller 18 waits for the management circuit 19 to send the program from the non-volatile memory 14 to the volatile memory 15 (“NO” of step “S4”). After the management circuit 19 sends the program (“YES” of step “S4”), the power supply controller 18 deactivates the first power supply 16 (step “S5”).

The power supply controller 18 waits for the power switch 13 to be turned on (“NO” of step “S6”). After the power switch 13 is turned on (“YES” of step “S6”), the power supply controller 18 activates the first power supply 16 (step “S7”) and sends a signal to the management circuit 19 indicating that the power switch 13 is turned on (step “S8”).

The power supply controller then waits for the power switch 13 to be turned off (“NO” of step “S9”). After the power switch 13 is turned off (“YES” of step “S9”), the power supply controller 18 deactivates the first power supply (step “S10”), and ends the processing (“END”).

FIG. 4 is a flow chart of processing of the management circuit 19 of the first embodiment. The management circuit 19 starts processing (“START”) after the first power supply 16 is activated. In a case where the program for initialization is not fully in the volatile memory 15 (“NO” of step “S11”), the management circuit 19 sends the program from the non-volatile memory 14 to the volatile memory 15 (step “S12”).

After sending the program (step “S13”), the management circuit 19 waits for the signal from the power supply controller 18 indicating that the power switch 13 is turned on (“NO” of step “S14”). In a case where the program is fully in the volatile memory 15 (“YES” of step “S11”), the steps “S12” and “S13” are bypassed.

After receiving the signal from the power supply controller 18 indicating that the power switch 13 is turned on (“YES” of step “S14”), the management circuit 19 causes the program to run, i.e., to initialize the electronic apparatus 1 and to get it ready to work (step “S15”).

According to the first embodiment described above, a time-consuming process of sending the program to the working memory may be completed before the power switch is turned on.

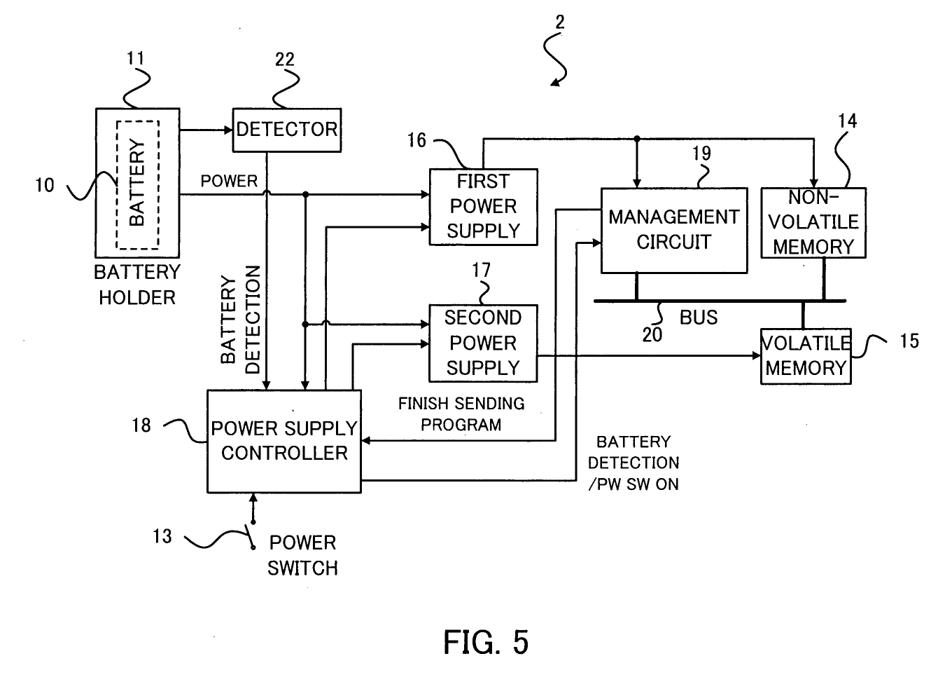

A second embodiment of the present invention will be described with reference to FIG. 5 through FIG. 9. FIG. 5 is a block diagram of an electronic apparatus 2 of the second embodiment, e.g. a mobile phone. The electronic apparatus 2 has a same configuration as the one of the electronic apparatus 1 shown in FIG. 1 except that the detector 12 in FIG. 1 is replaced by a detector 22 in FIG. 5.

Each of the other portions of the electronic apparatus 2 is a same as the corresponding one shown in FIG. 1 given the same reference numeral, and its explanation is omitted. The detector 22 detects the battery 10 placed in the battery holder 11 by measuring voltage of the output of the battery 10.

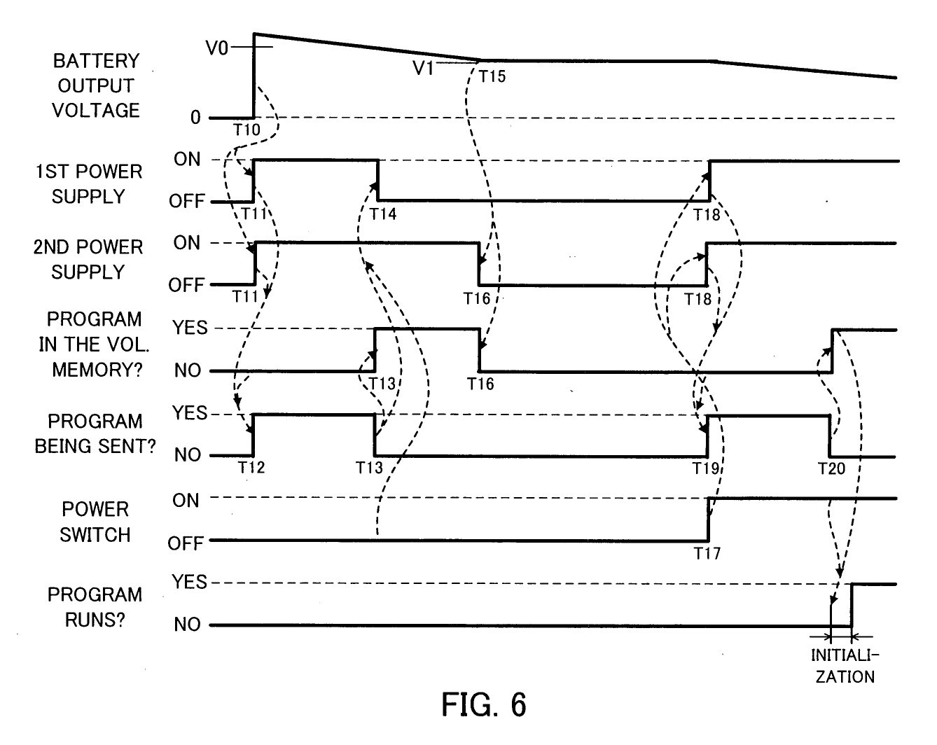

A first processing sequence of the second embodiment will be described with reference to a timing chart shown in FIG. 6. The timing chart includes seven state transitions similar to those shown in FIG. 2, except that it is affected by a change of the output voltage of the battery 10.

In the first state transition, the battery 10 is placed in the battery holder 11 at a time T10. The output voltage rises to a certain value no lower than a predetermined value V0 at T10. The detector 12 detects the battery 10 by measuring the output voltage of the battery 10 at T10. The power supply controller 18 is aware of the detection and the output voltage measured by the detector 12.

In a case where the measured output voltage of the battery 10 is no lower than V0, the power supply controller 18 activates the first power supply 16 and the second power supply 17 at a time T11 after T10. The management circuit 19 is activated after the first power supply 16 is activated. The power supply controller 18 sends a signal to the management circuit 19 indicating the detection at T11, as shown in FIG. 5, so that the management circuit 19 is aware that the detection causes the management circuit 19 to be activated.

The program for initialization is not fully in the volatile memory 15 at T11, and the management circuit 19 then starts to send the program from the non-volatile memory 14 to the volatile memory 15 at a time T12 after T1.

At a time T13, a certain period of time after T12, the management circuit 19 finishes sending the program. The program is fully in the volatile memory 15 and is ready to run after T13. The management circuit 19 sends a signal to the power supply controller 18 indicating that the management circuit 19 finishes sending the program as shown in FIG. 5. The power supply controller 18 then deactivates the first power supply 16 at a time T14 while the power switch 13 is turned off and after T13. The second power supply 17 keeps activated and keeps supplying power to the volatile memory 15 after T14.

The battery 10 keeps supplying the second power supply 17 with power and may leak currents in addition, and thereby continuously discharges so that the output voltage of the battery 10 gradually drops after T10. The power supply controller 18 keeps watching the output voltage of the battery 10 through the detector 22 after T10, comparing to a threshold V1. The value V0 and the threshold V1 will be used in following embodiments, too.

As long as the output voltage of the battery 10 is no lower than V1, the electronic apparatus 2 works for a certain period of time after the power switch 13 is turned on, e.g., being capable of a five-minute voice communication. The power supply controller 18 thus keeps activating the second power supply 17 so that the program in the volatile memory 15 is not broken.

V1 may be lower than V0 as the battery 10 discharges while the second power supply 16 keeps activated between T11 and T14. V1 may equal V0 in a case where an effect of deactivating the first power supply 16 at T14 is not significant.

In a case where the power switch is turned on before the output voltage of the battery 10 drops to V1 (not shown), the electronic apparatus 1 follows a same sequence as the one shown in FIG. 2, particularly a part of it after T5.

In a case where the output voltage of the battery 10 drops to V1 as shown in FIG. 6 at a time T15 after T14, the power supply controller 18 deactivates the second power supply 17 at a time T16 after T15. That is a fail-safe process dealing with an unallowable voltage drop. The battery 10 may thereby keep the output voltage around V1.

Although the program in the volatile memory 15 is broken at T16 and needs a time-consuming process of sending the program again after the power switch 13 is turned on, the battery 10 keeps the output voltage around V1 and may thereby enable the electronic apparatus 1 to work for a certain period of time after the power switch 13 is turned on, e.g., being capable of a five-minute voice communication.

At a time T17 after T16, the power switch 13 is turned on. The power supply controller 18 is aware that the power switch 13 is turned on, and then activates the first power supply 16 and the second power supply 17 at a time T18 after T17. The power supply controller 18 sends a signal to the management circuit 19 indicating that the power switch 13 is turned on as shown in FIG. 5.

The program is not fully in the volatile memory 15 at T18, as it has been broken at T16. The management circuit 19 then starts to send the program from the non-volatile memory 14 to the volatile memory 15 at a time T19 after T18.

At a time T20, a certain period of time after T19, the management circuit 19 finishes sending the program from the non-volatile memory 14 to the volatile memory 15. After T20, the power switch 13 is turned on and the program is fully in the volatile memory 15. The management circuit 19 then causes the program to run, i.e., to initialize the electronic apparatus 1 and get it ready to work.

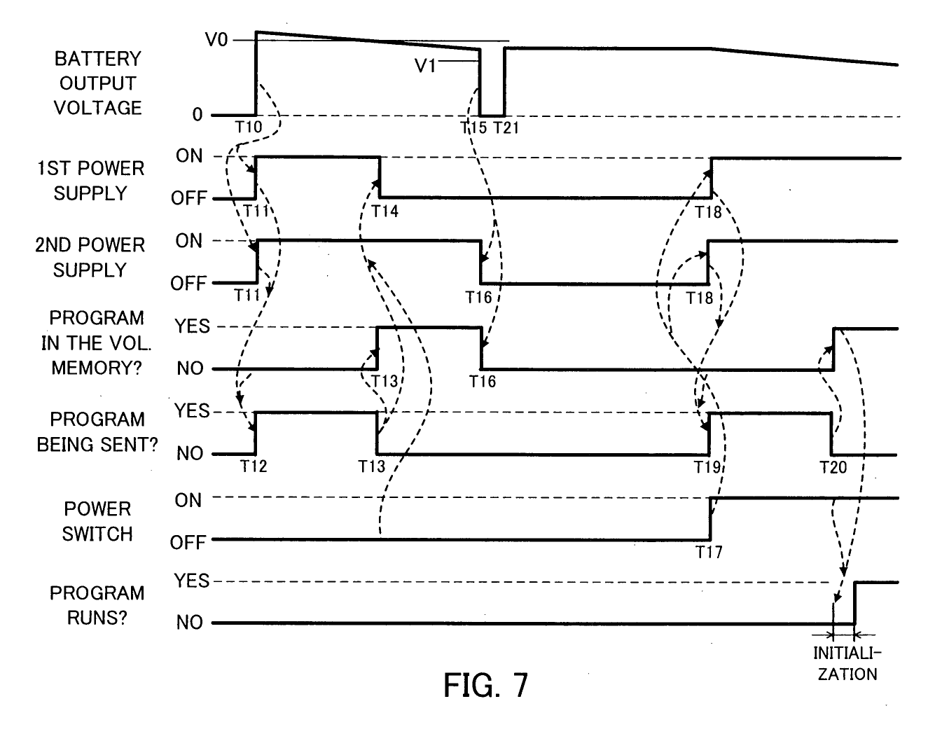

A second processing sequence of the second embodiment will be described with reference to a timing chart shown in FIG. 7. This timing chart is almost a same as the one shown in FIG. 6, and thus each of the timing symbols T10 through T20 indicating each time of the sequence shown in FIG. 6 is also used in FIG. 7.

At T15 in FIG. 7, though, the output voltage of the battery 10 goes down to zero before gradually dropping to V1. This may be caused by an occasion of removal of the battery 10 from the battery holder 11, or short-time disconnection between the electrode of the battery 10 and the contact of the battery holder 11 resulting from a vibration or a fall of the electronic apparatus 1.

The first power supply 16 and the second power supply 17 are thereby deactivated, and the program in the volatile memory 15 is broken at T16 as in FIG. 6. The output voltage of the battery 10 recovers at a time T21 after T15. In a case where the voltage is lower than V0 at T21, the power supply controller 18 keeps than V0 at T21, the power supply controller 18 keeps deactivating the first power supply 16 and the second power supply 17, as shown in FIG. 7.

That is a fail-safe process dealing with occasions of removal or short-time disconnection of the battery 10. The battery 10 may thus keep the output voltage no lower than V1. Even though such occasions of removal or short-time disconnection of the battery 10 repeatedly occur, the battery 10 may keep the output voltage no lower than V1 so that the electronic apparatus 1 may work at least for a certain period of time after the power switch 13 is turned on.

In a case where the voltage is no lower than V0 at T21 (not shown), the first power supply 16 and the second power supply 17 are activated and the program is sent from the non-volatile memory 14 to the volatile memory 15 again.

Although the program in the volatile memory 15 is broken at T16 and needs a time-consuming process of sending the program again after the power switch 13 is turned on, the battery 10 keeps the output voltage no lower than V1 and may enable the electronic apparatus 1 to work for a certain period of time after the power switch 13 is turned on, e.g., being capable of a five-minute voice communication.

In a case where such occasions of removal or short-time disconnection of the battery 10 do not often occur, the power supply controller 18 may activate the first power supply 16 and the second power supply 17 every time the battery 10 recovers from the removal or the disconnection no matter if the output voltage is lower or no lower than V0.

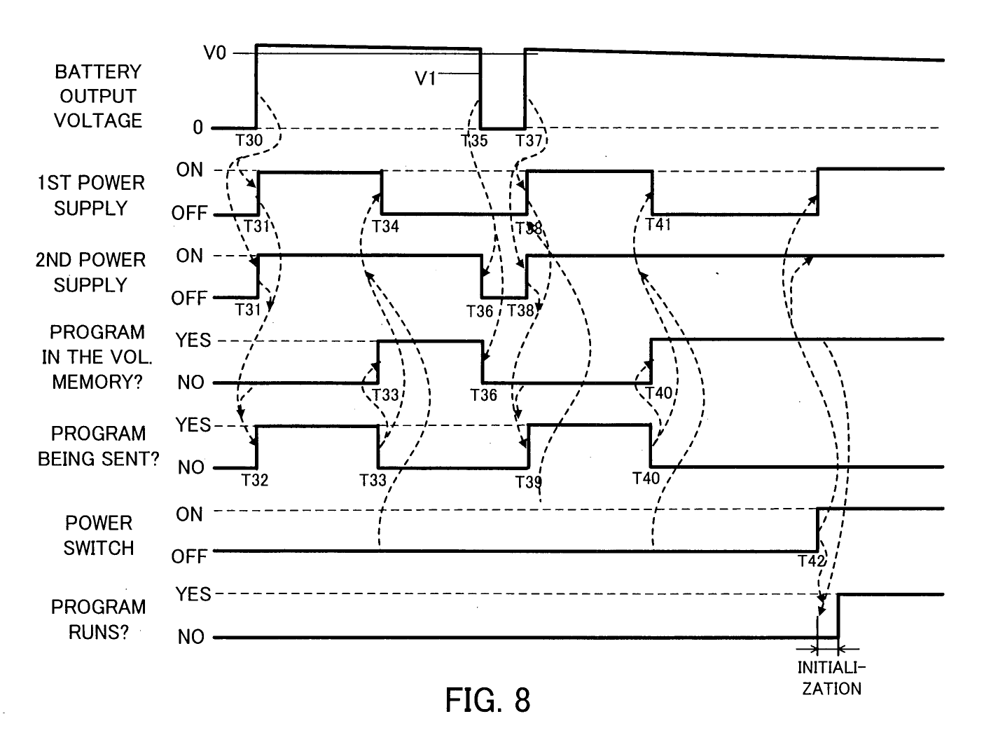

A third processing sequence of the second embodiment will be described with reference to a timing chart shown in FIG. 8. This timing chart includes seven state transitions similar to those shown in FIG. 6 or FIG. 7.

In the first state transition, the battery 10 is placed in the battery holder 11 at a time T30. The output voltage rises to a certain value no lower than V0 at T30. The power supply controller 18 activates the first power supply 16 and the second power supply 17 at a time T31 after T30. The management circuit 19 starts to send the program from the non-volatile memory 14 to the volatile memory 15 at a time T32 after T31.

At a time T33, a certain period of time after T32, the management circuit 19 finishes sending the program. The power supply controller 18 then deactivates the first power supply 16 at a time T34 while the power switch 13 is turned off and after T33. The second power supply 17 keeps activated and keeps supplying the volatile memory 15 with power after T34. The sequence between T30 and T34 is equivalent to the sequence between T0 and T4 shown in FIG. 2.

Although the battery 10 continuously discharges, the output voltage of the battery 10 goes down to zero before gradually dropping to V1 because of an occasion of removal or short-time disconnection of the battery 10 as described with reference to FIG. 7. The first power supply 16 and the second power supply 17 are thereby deactivated, and the program in the volatile memory 15 is broken at a time T36 after T35.

The output voltage of the battery 10 recovers at a time T37 after T36. In a case where the recovered output voltage of the battery 10 is no lower than V0 at T37, the power supply controller 18 activates the first power supply 16 and the second power supply 17 at a time T38 after T37. The program is not fully in the volatile memory 15 at T38. The management circuit 19 then starts to send the program from the non-volatile memory 14 to the volatile memory 15 at a time T39 after T38.

At a time T40, a certain period of time after T39, the management circuit 19 finishes sending the program. The power supply controller 18 then deactivates the first power supply 16 at a time T41 while the power switch 13 is turned off and after T40. The second power supply 17 keeps activated and supplying the volatile memory 15 with power after T41. The sequence between T37 and T41 is equivalent to the sequence between T30 and T34.

The power supply controller 18 keeps watching the output voltage of the battery 10 through the detector 22 after T41, comparing to V1. The power switch 13 is turned on at a time T42 after T41, before the output voltage drops to V1. The power supply controller 18 is aware that the power switch 13 is turned on, and then activates the first power supply 16 and the second power supply 17. The power supply controller 18 actually keeps the second power supply 17 activated. The program is fully in the volatile memory 15 at T42.

The management circuit 19 then causes the program in the volatile memory 15 to run, i.e., to initialize the electronic apparatus 2 and get it ready to work. The sequence after T42 is equivalent to the sequence after T5 shown in FIG. 2.

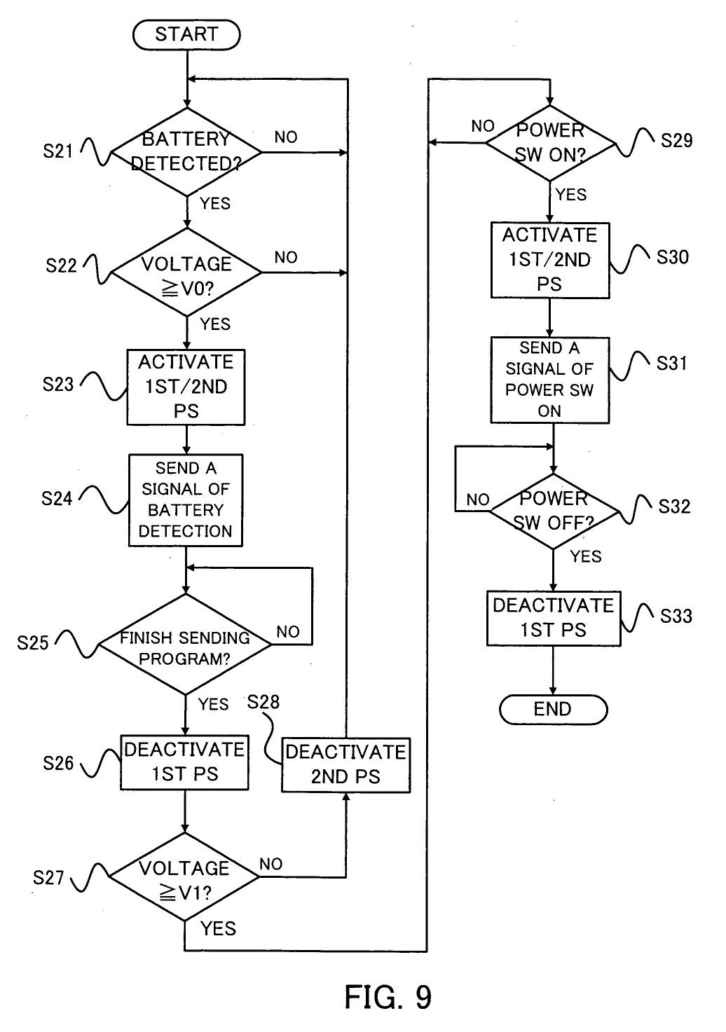

FIG. 9 is a flow chart of processing of the power supply controller 18 of the second embodiment. The power supply controller 18 starts processing (“START”) and waits for the detector 11 to detect the battery 10 (“NO” of step “S21”). After the detection (“YES” of step “S21”), the power supply controller 18 is aware of the measured output voltage of the battery 10.

In a case where the output voltage is lower than V0 (“NO” of step “S22”), the flow goes back to the beginning. In a case where the output voltage is no lower than V0 (“YES” of step “S22”), the flow goes forward. Following steps “S23” through “S26” are equal to the steps “S2” through “S5” shown in FIG. 3, and their explanations are omitted.

In a case where the output voltage of the battery 10 is lower than V1 (“NO” of step “S27”), the power supply controller 18 deactivates the second power supply 17 (step “S28”) and the flow goes back to the beginning. In a case where the output voltage is no lower than V1 (“YES” of step “S27”), the flow goes forward. Following steps “S29” through “S33” are equal to the steps “S6” through “S10” shown in FIG. 3, and their explanations are omitted.

A flow chart of processing of the management circuit 19 in the second embodiment is equal to that shown in FIG. 4.

According to the second embodiment described above, the program sent and written to the volatile memory may be recovered in a fail-safe manner in a case where a voltage drop or a failure of the battery occurs.

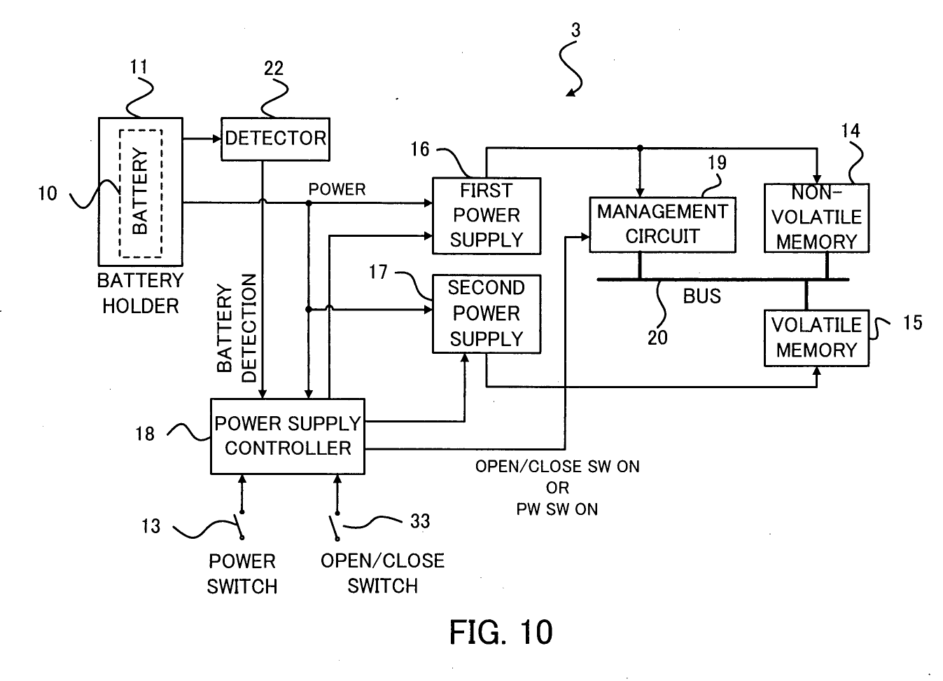

A third embodiment of the present invention will be described with reference to FIG. 10 through FIG. 12. FIG. 10 is a block diagram of an electronic apparatus 3 of the third embodiment, e.g. a mobile phone. The electronic apparatus 3 is configured in a first housing (not shown) and a second housing (not shown) connected to each other and configured to open and close to each other.

In terms of the block diagram, however, the electronic apparatus 3 has a same configuration as the one of the electronic apparatus 2 shown in FIG. 5, except for further having an open/close switch 33. The open/close switch 33 is turned on after the first and the second housings open to each other. Each of the other portions of the electronic apparatus 3 is a same as the corresponding one shown in FIG. 5 given the same reference numeral, and its explanation is omitted.

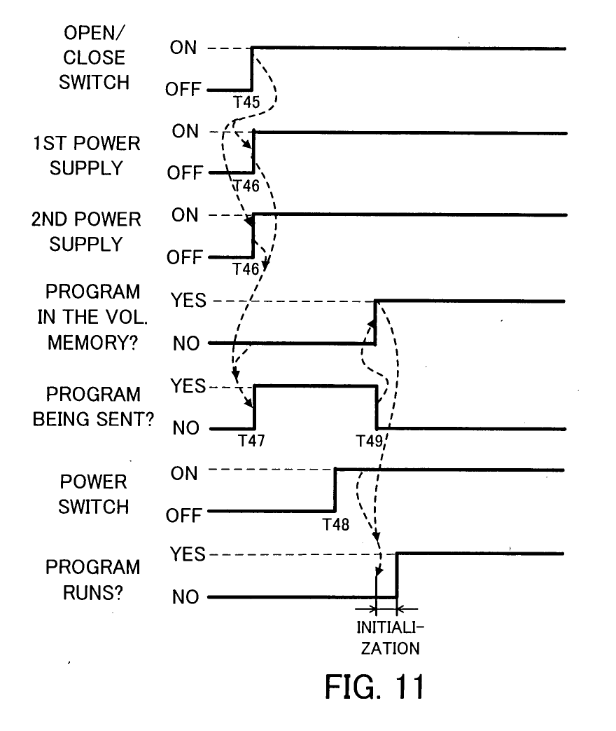

A processing sequence of the third embodiment will be described with reference to a timing chart shown in FIG. 11. Although the timing chart includes seven state transitions similar to those shown in FIG. 6, the first one is a state transition of the open/close switch 33, not the output voltage of the battery 10.

Suppose that the battery 10 has been placed in the battery holder 11 and the output voltage is no lower than V0, and that the first power supply 16 and the second power supply 17 have been deactivated. The open/close switch 33 is turned on at a time T45. The power supply controller 18 is aware that the open/close switch 33 is turned on, and then activates the first power supply 16 and the second power supply 17 at a time T46 after T45. The management circuit 19 is activated after the first power supply 16 is activated. The power supply controller 18 sends a signal to the management circuit 19 indicating that the open/close switch 33 is turned on as shown in FIG. 10, so that the management circuit 19 is aware that the open/close switch 33 having been turned on causes the management circuit 19 to be activated.

The program is not fully in the volatile memory 15 at T46, as the second power supply has been deactivated before T46, and the management circuit 19 then starts sending the program from the non-volatile memory 14 to the volatile memory 15 at a time T47 after T46.

At a time T48 after T47, the power switch 13 is turned on. The power supply controller 18 is aware that the power switch 13 is turned on, and keeps the first power supply 16 and the second power supply 17 activated. The power supply controller 18 sends a signal to the management circuit 19 indicating that the power switch 13 is turned on as shown in FIG. 10. At T48, the management circuit 19 starts a preparatory process, e.g., showing information of a fixed form on a display (not shown in FIG. 10), after receiving the signal indicating that the power switch 13 is turned on.

At a time T49 after T48 and a certain period of time after T47, the management circuit 19 finishes sending the program from the non-volatile memory 14 to the volatile memory 15. After T49, the power switch 13 has been turned on and the program is fully in the volatile memory 15. The management circuit 19 causes the program to run, i.e., to initialize the electronic apparatus 3 and get it ready to work.

The electronic apparatus 1 waits for the management circuit 19 to finish sending the program between T48 and T49. This time interval is shorter than the time interval between T47 and T49 that is required in a case where the power switch 13 having been turned on causes the first power supply 16 and the second power supply 17 to be activated.

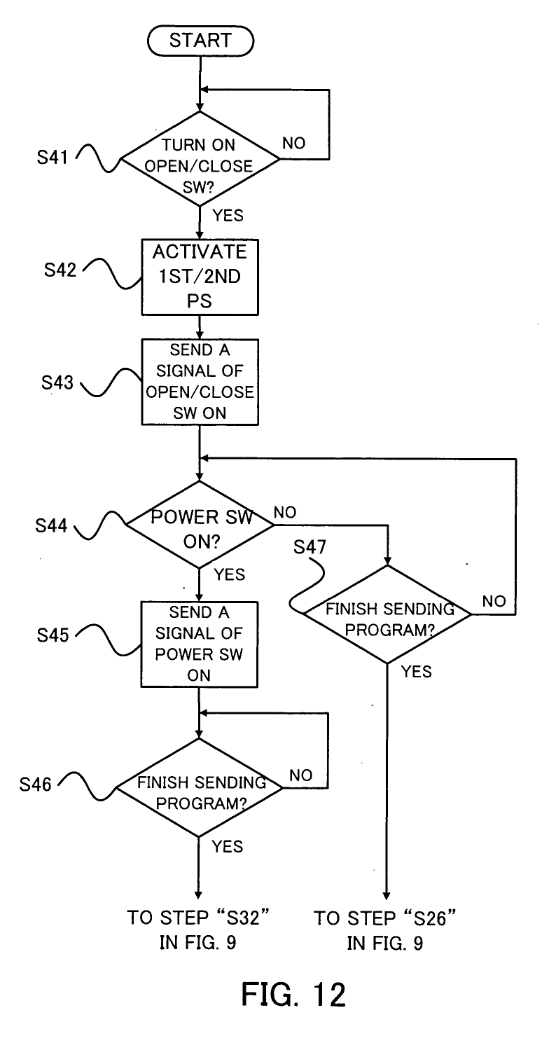

FIG. 12 is a flow chart of processing of the power supply controller 18 of the third embodiment. The power supply controller 18 starts processing (“START”) and waits for the open/close switch 33 to be turned on (“NO” of step “S41”). After the open/close switch 33 is turned on (“YES” of step “S41”), the power supply controller activates the first power supply 16 and the second power supply 17 (step “S42”), and sends a signal to the management circuit 19 indicating that the open/close switch 33 is turned on (step “S43”).

The power supply controller 18 waits for the power switch 13 to be turned on. After the power switch 13 is turned on (“YES” of step “S44”), the power supply controller 18 sends a signal to the management circuit 19 indicating that the power switch 13 is turned on (step “S45”).

The power supply controller 18 waits for the management circuit 19 to finish sending the program from the non-volatile memory 14 to the volatile memory 15 (“NO” of step “S46”). After the management circuit 19 finishes sending the program (“YES” of step “S46”), the flow goes to a series of steps equivalent to the steps “S32” and “S33” shown in FIG. 9.

In a case where the power switch 13 remains deactivated (“NO” of step “S44”), the power supply controller 18 waits for the management circuit 19 to finish sending the program from the non-volatile memory 14 to the volatile memory 15. While the management circuit 19 keeps sending the program, the flow goes back to the step “S44” (“NO” of step “S47”). In a case where the management circuit 19 finishes sending the program before the power switch 13 is turned on, the flow goes to a series of steps equivalent to the steps “S26” through “S33” shown in FIG. 9.

According to the third embodiment described above, the time interval needed to wait for the management circuit 19 to finish sending the program is shorter than the time interval needed in a case where the power switch having been turned on causes the first power supply and the second power supply to be activated.

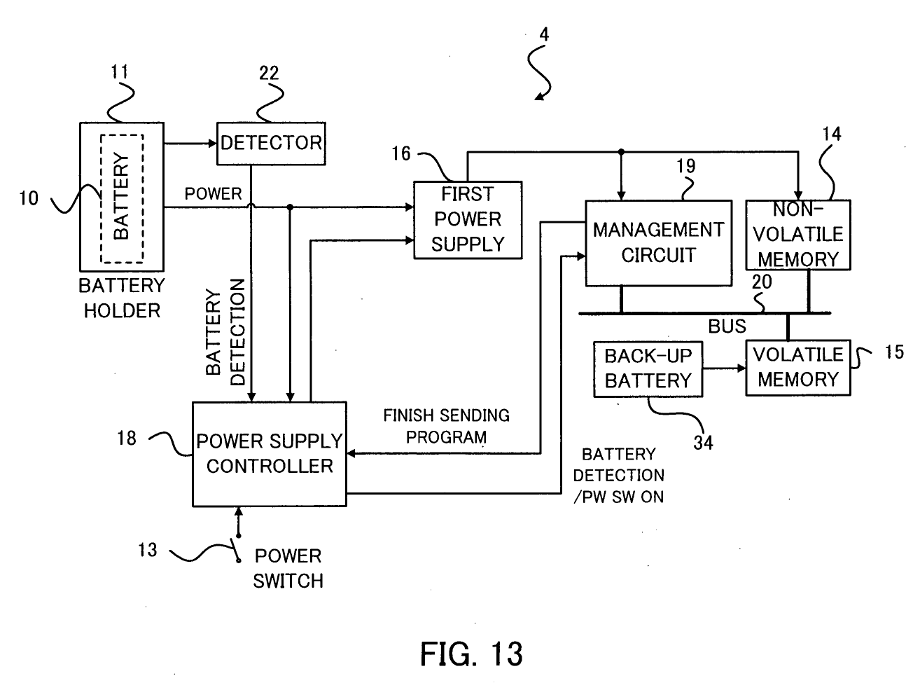

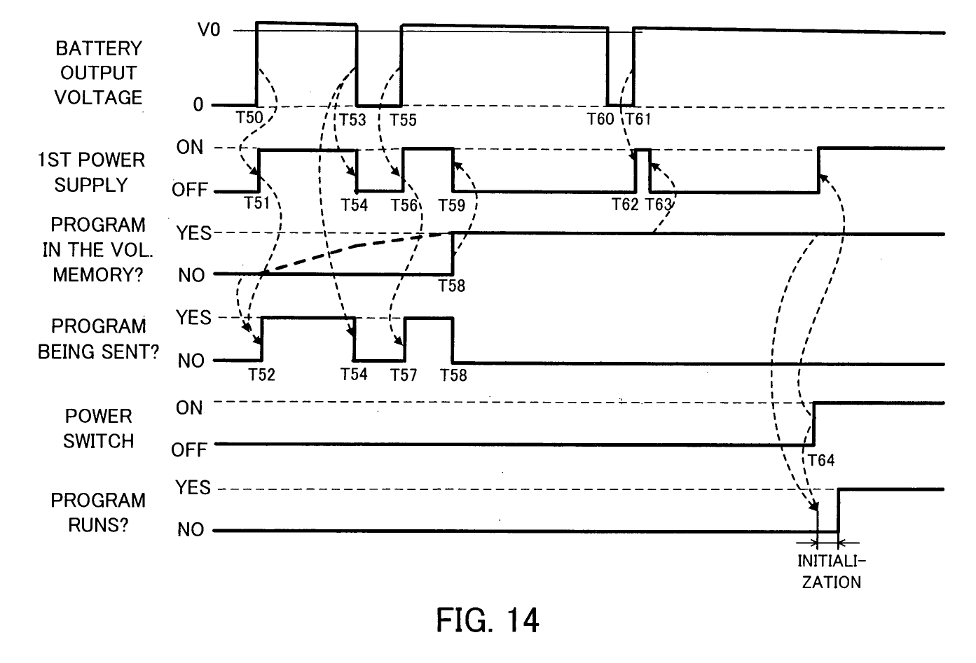

A fourth embodiment of the present invention will be described with reference to FIG. 13 and FIG. 14. FIG. 13 is a block diagram of an electronic apparatus 4 in the fourth embodiment, e.g. a mobile phone. The electronic apparatus 4 has a same configuration as the one of the electronic apparatus 2 shown in FIG. 5, except for having a back-up battery 34 continuously supplying the volatile memory 15 with power instead of the second power supply 17. Each of the other portions of the electronic apparatus 4 is a same as the corresponding one shown in FIG. 5 having the same reference numeral, and its explanation is omitted.

A processing sequence of the fourth embodiment will be described with reference to a timing chart shown in FIG. 14. The timing chart includes six state transitions similar to those shown in FIG. 8, excluding a state transition of the second power supply.

In the first state transition, the battery 10 is placed in the battery holder 11 at a time T50. The output voltage rises to a certain value no lower than V0 at T50. The power supply controller 18 activates the first power supply 16 at a time T51 after T50. The management circuit 19 starts to send the program from the non-volatile memory 14 to the volatile memory 15 at a time T52 after T51. A part of the program having been sent and written to the volatile memory 15 is shown by a slant dashed line overlaid on the third state transition.

At a time T53 after T52, the output voltage of the battery 10 goes down to zero because of an occasion of removal or short-time disconnection of the battery 10 as described with reference to FIG. 7. The first power supply 16 is thereby deactivated at T54 after T53.

In a case where the management circuit 19 has not finished sending the program for initialization from the non-volatile memory 14 to the volatile memory 15 at T54, the volatile memory 15 stores a part of the program having been sent and written to the volatile memory 15 before T54. That part of the program is not broken as the back-up battery 34 keeps supplying the volatile memory 15 with power.

The output voltage of the battery 10 recovers at a time T55 after T54. In a case where the recovered output voltage of the battery 10 is no lower than V0 at T55, the power supply controller 18 activates the first power supply 16 at a time T56 after T55. The management circuit 19 resumes sending the program, i.e., starts sending a rest of the program not having been sent to the volatile memory 15, from the non-volatile memory 14 to the volatile memory 15 at a time T57 after T56.

At a time T58, a certain period of time after T57, the management circuit 19 finishes sending the program. The power supply controller 18 then deactivates the first power supply 16 at a time T59 after T58.

At a time T60 after T59, the output voltage of the battery 10 goes down to zero because of another occasion of removal or short-time disconnection of the battery 10. The output voltage of the battery 10 then recovers at a time T61 after T60, and the first power supply 16 is activated at a time T62 after T61. The power supply controller 18 deactivates the first power supply 16 at a time T63 shortly after T62, as the program for initialization is fully in the volatile memory 15.

Even though such occasions of removal or short-time disconnection of the battery 10 repeatedly occur, the first power supply 16 is activated only for a short time on each occasion. The battery 10 may thereby decrease power consumption.

The power switch 13 is turned on at a time T64 after T63, before the output voltage drops to V1. The power supply controller 18 then activates the first power supply 16, and the management circuit 19 causes the program in the volatile memory 15 to run, as in the sequence after T42 shown in FIG. 8.

According to the fourth embodiment described above, the management circuit may send the program part by part in a case where an occasion of short-time disconnection of the battery happens while the program is being sent, and the battery may decrease power consumption.

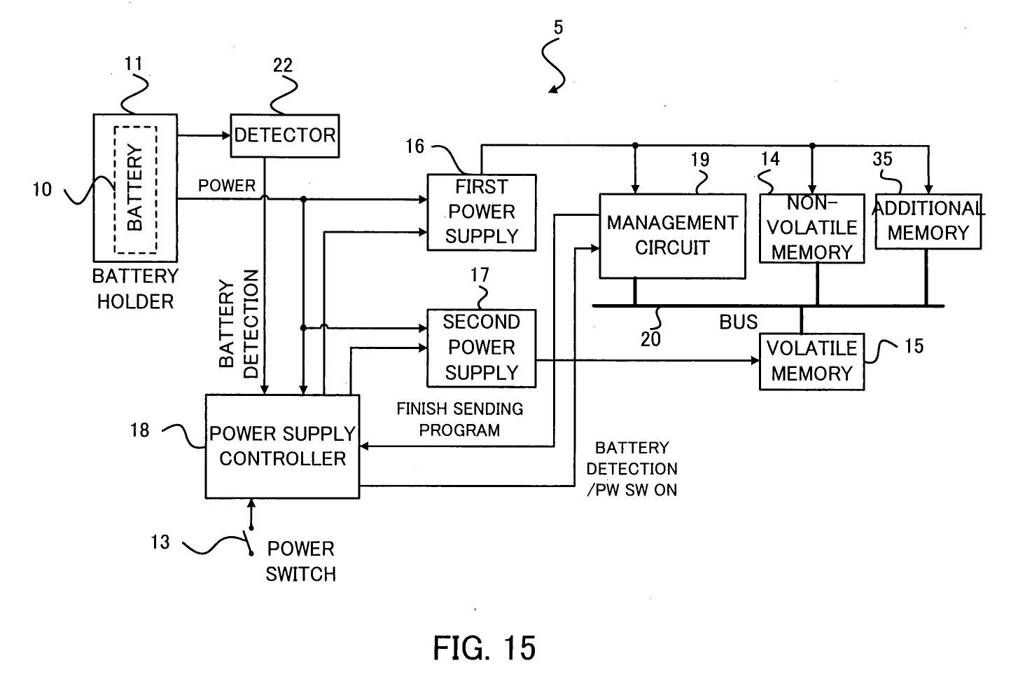

A fifth embodiment of the present invention will be described with reference to FIG. 15 through FIG. 18. FIG. 15 is a block diagram of an electronic apparatus 5 of the fifth embodiment, e.g. a mobile phone. The electronic apparatus 5 has a same configuration as the one of the electronic apparatus 2 shown in FIG. 5 except for further having an additional memory 35. Each of the other portions of the electronic apparatus 5 is a same as the corresponding one shown in FIG. 5 given the same reference numeral, and its explanation is omitted.

The additional memory 35 is configured to store a plurality of specified data, and is blank at shipment. The specified data are, e.g., pieces of information regarding a subscriber purchasing the electronic apparatus 5, a mobile phone. The specified data are written to the additional memory 35 with a specific writer (not shown) at a shop where the electronic apparatus 5 is purchased.

The additional memory 35 may be included in the non-volatile memory 14. The additional memory 35 may be included in an LSI forming the management circuit 19 so that the specified data written thereto may hardly be read out to improve secrecy.

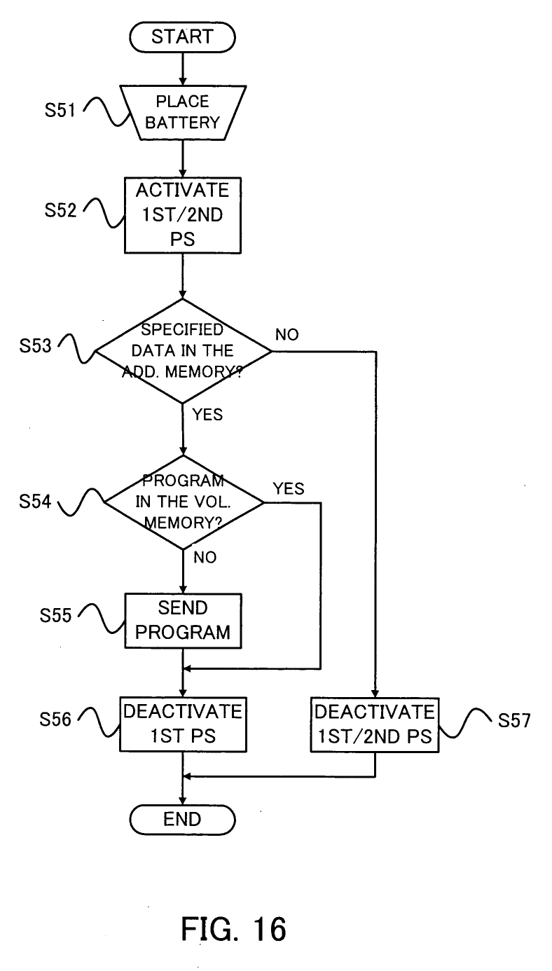

FIG. 16 is a first flow chart of processing of the electronic apparatus 5 of the fifth embodiment. The flow of processing is controlled by a combination of the power supply controller 18 and the management circuit 19, exchanging signals to each other and working together as described in the previous embodiments.

To begin with (“START”), the battery 10 is placed in the battery holder 11 (step “S51”). The power supply controller 18 activates the first power supply 16 and the second power supply 17, after the battery 10 is detected by the detector 12 (step “S52”). The power supply controller 18 sends a signal to the management circuit 19 indicating the detection as shown in FIG. 15 and as described in the previous embodiments.

The management circuit 19 then finds out if the specified data have been written to the additional memory 35. In a case where the specified data are written to the additional memory 35 (“YES” of step “S53”), the management circuit 19 finds out if the program for initialization is fully in the volatile memory 15.

In a case where the program is not fully in the volatile memory 15 (“NO” of step “S54”), the management circuit 19 sends the program from the non-volatile memory 14 to the volatile memory 15 (step “S55”). In a case where the program is in the volatile memory 15 (“YES” of step “S54”), the step “S55” is bypassed.

After sending the program, the management circuit 19 sends a signal to the power supply controller 18 indicating that the program has been sent to the volatile memory 15, as shown in FIG. 15. The power supply controller 18 then deactivates the first power supply 16 (step “S56”). The flow of processing ends where the first power supply 16 keeps deactivated, the second power supply 17 keeps activated and the program is fully in the volatile memory 15 (“END”).

In a case where the specified data are not written to the additional memory 35 (“NO” of step “S53”), the management circuit 19 informs the power supply controller 18 that the additional memory 35 stores none of the specified data. The power supply controller then deactivates the first power supply 16 and the second power supply 17. The flow of processing ends here (“END”) while the first power supply 16 and the second power supply 17 keep deactivated and the program is not fully in the volatile memory 15.

Before shipment from a factory, the flow of processing follows the steps “S51”, “S52”, “NO” of “S53” and “S57”, as the specified data have not been written to the additional memory 35. The electronic apparatus 5 may keep a state of low power consumption, as the first power supply 16 and the second power supply 17 keep deactivated.

The electronic apparatus 5 may thus keep the battery 10 discharging little while going through a distribution channel. The battery 10 may remain charged enough so that the specified data are written to the additional memory 35 at a shop, after the electronic apparatus 5 is purchased. The battery 10 may remain charged enough so that the electronic apparatus 5 may work for a five-minute voice communication, e.g., just after being purchased.

Suppose that the battery 10 is removed from the battery holder 11 and is placed in the battery holder 11 again, after the specified data are written to the additional memory 35. The flow of processing follows the steps “S51”, “S52”, “YES” of “S53” and “S54” through “S56”, as described in the first embodiment except for the step “S53”.

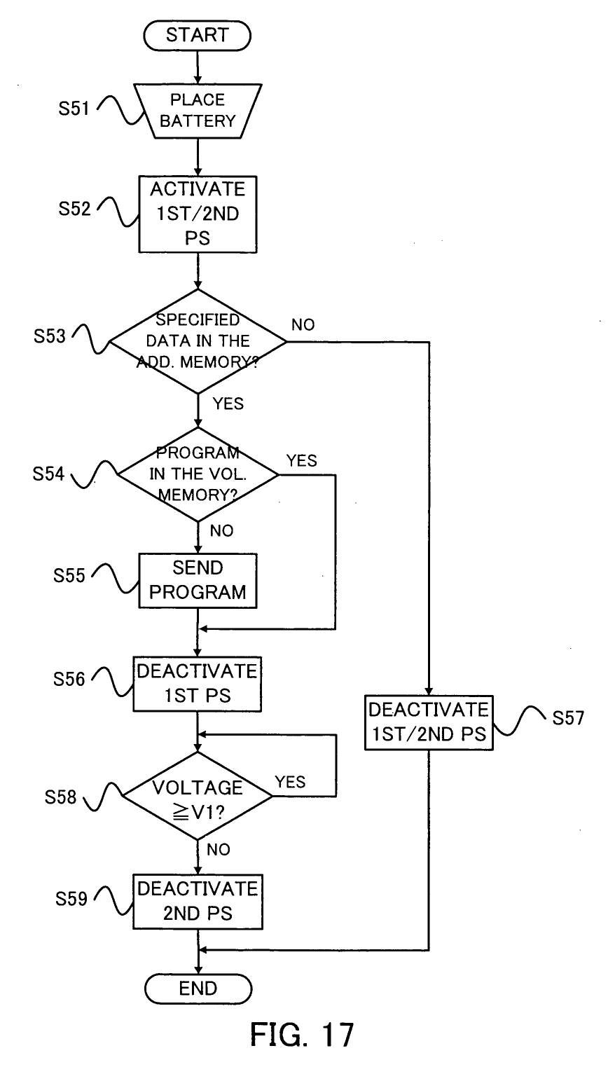

FIG. 17 is a second flow chart of processing of the electronic apparatus 5 of the fifth embodiment. Each of the steps “S51” through “S57” is a same as the corresponding one given the same reference numeral shown in FIG. 16, and its explanation is omitted. After deactivating the first power supply 16 (step “S56”), the power supply controller 18 keeps watching the output voltage of the battery 10 through the detector 22 comparing to V1 (“YES” of “S58”). In a case where the output voltage is lower than V1 (“NO” of step “S58”), the power supply controller 18 deactivates the second power supply 17 (step “S59”) and the flow of processing ends where the first power supply 16 and the second power supply 17 keep deactivated and the program is not fully in the volatile memory 15 (“END”).

The flow of processing following the steps “S51” “S52”, “YES” of “S53” and “S54” through “S59” shown in FIG. 17 is equivalent to the flow described in the second embodiment except for the step “S53”.

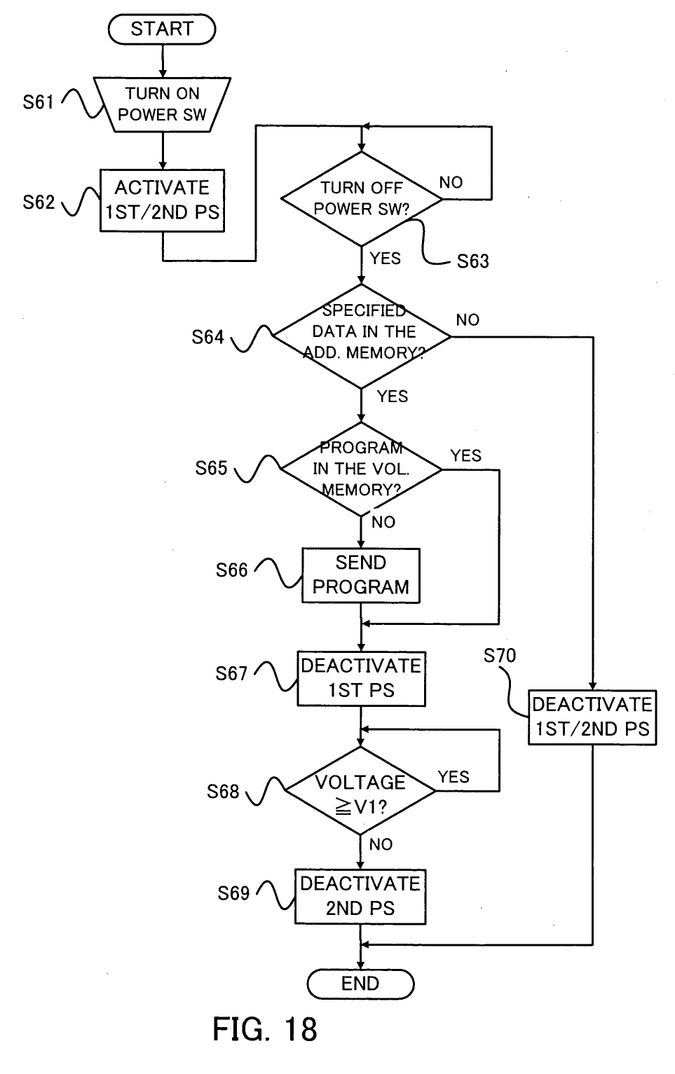

FIG. 18 is a third flow chart of processing of the electronic apparatus 5 of the fifth embodiment. Suppose, at first, that the battery 10 is placed in the battery holder 11 and the power switch 13 is turned off.

To begin with (“START”), the power switch 13 is turned on (step “S61”). The power supply controller 18 then activates the first power supply 16 and the second power supply 17 (step “S62”). The management circuit 19 receives a signal from the power supply controller 18 indicating that the power switch 13 is turned on, and causes the program in the volatile memory 15 to run as described in the previous embodiments, although not shown in FIG. 18.

The power supply controller 18 waits for the power switch 13 turned off (“NO” of step “S63”). In a case where the power switch 13 is turned off (“YES” of step “S63”), the power supply controller 18 sends a signal to the management circuit 19 indicating that the power switch 13 is turned off. The management circuit 19 then finds out if the specified data have been written to the additional memory (step “S64”). The steps “S64” through “S70” equal to the steps “S53” through “S59” and their explanations are omitted.

As the program for initialization may be fully in the volatile memory 15 that keeps activated as long as the output voltage of the battery 10 is no lower than V1, the management circuit 19 may cause the program to run just after the power switch 13 is turned on next time.

The electronic apparatus 5 may have a same configuration as the one of the electronic apparatus 1 shown in FIG. 1 except for further having an additional memory 35. In that case, the steps “S58” and “S59” are deleted in FIG. 17, and the steps “S68” and “S69” are deleted in FIG. 18.

In the fifth embodiment, the power switch 13 may be an automatic switch with a timer (not shown), and may be turned off after a preset period of time passes after a last operation is done on the electronic apparatus 5.

The electronic apparatus 5 may be configured in a first housing (not shown) and a second housing (not shown connected to each other and configured to open and close to each other. In that case, the management circuit 19 may find out if the specified data are in the additional memory after the first housing and the second housing close to each other. This is implemented by, e.g., using the open/close switch 33 shown in FIG. 10.

According to the fifth embodiment described above, the battery may be charged enough after the electronic apparatus goes through a distribution channel, and the electronic apparatus may start working immediately after the power switch is turned on.

What is claimed is:

1. An electronic apparatus comprising:
a battery holder:
a detector for detecting a battery placed in the battery holder;
a non-volatile memory for storing a program for initialization;
a volatile memory;
a first power supply for supplying the non-volatile memory with power from the battery placed in the battery holder;
a second power supply for supplying the volatile memory with power from the battery placed in the battery holder;
a power switch for causing the first power supply and the second power supply to be activated;
a power supply controller for activating the first power supply and the second power supply after the detector detects the battery, and for activating the first power supply and the second power supply after the power switch is turned on; and
a management circuit for sending the program from the non-volatile memory to the volatile memory after the first power supply and the second power supply are activated and before the program is fully sent to the volatile memory, for causing the power supply controller to deactivate the first power supply after sending the program and before the power switch is turned on, and for causing the program in the volatile memory to run after the power switch is turned on.

2. The electronic apparatus of claim 1, wherein the power switch is one of a manual switch and an automatic switch with a timer.

3. The electronic apparatus of claim 1, wherein the detector detects the battery placed in the battery holder by sensing voltage of the output of the battery.

4. The electronic apparatus of claim 1, wherein the detector further measures voltage of an output of the battery placed in the battery holder, and the power supply controller activates the first power supply and the second power supply after the detector detects the battery wherein the measured voltage of the output of the battery is no lower than a predetermined value.

5. The electronic apparatus of claim 1, wherein the detector further measures voltage of an output of the battery placed in the battery holder, and the power supply controller further deactivates the second power supply after the measured voltage of the output of the battery falls below a threshold and before the power switch is turned on.

6. The electronic apparatus of claim 1 configured in a first housing and a second housing connected to each other and configured to open and close to each other, wherein the power switch is configured to be turned on after the first housing and the second housing open to each other.

7. The electronic apparatus of claim 1 configured in a first housing and a second housing connected to each other and configured to open and close to each other, and further comprising an additional switch configured to be turned on after the first housing and the second housing open to each other, wherein the power supply controller further acivates the first power supply and the second power supply after the additional switch is turned on.

8. An electronic apparatus comprising:
a battery holder:
a detector for detecting a battery placed in the battery holder and measuring voltage of an output of the battery;
a non-volatile memory for storing a program for initialization;
a volatile memory;
a power supply for supplying the non-volatile memory with power from the battery placed in the battery holder;
a back-up battery supplying the volatile memory with power;
a power switch for causing the power supply to be activated;
a power supply controller for activating the power supply after the detector detects the battery and for activating the power supply after the power switch is turned on; and
a management circuit for sending the program from the non-volatile memory to the volatile memory after the power supply is activated and before the program is fully sent to the volatile memory, for causing the power supply controller to deactivate the power supply after sending the program and before the power switch is turned on, and for causing the program in the volatile memory to run after the power switch is turned on.

9. The electronic apparatus of claim 8, wherein the management circuit further resumes sending the program after the power supply is deactivated while the program is being sent and deactivated thereafter.

10. An electronic apparatus comprising:
a battery holder:
a detector for detecting a battery placed in the battery holder and measuring voltage of an output of the battery;
a non-volatile memory for storing a program for initialization;
a volatile memory;
an additional memory for storing a plurality of specified data;
a first power supply for supplying the non-volatile memory and the additional memory with power from the battery placed in the battery holder;
a second power supply for supplying the volatile memory with power from the battery placed in the battery holder;
a power switch for causing the first power supply and the second power supply to be activated;
a power supply controller for activating the first power supply and the second power supply after the detector detects the battery, and for activating the first power supply and the second power supply after the power switch is turned on; and
a management circuit for finding out if a plurality of specified data is stored in the additional memory after the first power supply and the second power supply are activated and before the power switch is turned on, for sending the program from the non-volatile memory to the volatile memory after finding out that the specified data are stored in the additional memory, for causing the power supply controller to deactivate the first power supply after sending the program, and for causing the power supply controller to deactivate the first power supply and the second power supply after finding out that the specified data are out of the additional memory.

11. The electronic apparatus of claim 10, wherein the power supply controller further deactivates the second power supply after the management circuit sends the program and the measured voltage of the output of the battery falls below a threshold.

12. The electronic apparatus of claim 10, wherein the management circuit further finds out if the specified data are stored in the additional memory after the power switch is turned off.

13. The electronic apparatus of claim 10, wherein the power switch has a timer therein and the management circuit further finds out if the specified data are stored in the additional memory after the power switch is automatically turned off as controlled by the timer.

14. The electronic apparatus of claim 10 configured in a first housing and a second housing connected to each other and configured to open and close to each other, and further comprising an additional switch configured to be turned off after the first housing and the second housing close to each other, wherein the management circuit further finds out if the specified data are stored in the additional memory after the additional switch is turned off.

15. The electronic apparatus of claim 10, wherein the management circuit further finds out if the specified data are stored in the additional memory after the power switch is turned off, and the power supply controller further deactivates the second power supply after the measured voltage of the output of the battery falls below a threshold.

16. The electronic apparatus of claim 10, wherein the power switch has a timer therein and the management circuit further finds out if the specified data are stored in the additional memory after the power switch is automatically turned off as controlled by the timer, and the power supply controller further deactivates the second power supply after the measured voltage of the output of the battery falls below a threshold.

17. The electronic apparatus of claim 10 configured in a first housing and a second housing connected to each other and configured to open and close to each other, and further comprising an additional switch configured to be turned off after the first housing and the second housing close to each other, wherein the management circuit further finds out if the specified data are stored in the additional memory after the additional switch is turned off, and the power supply controller further deactivates the second power supply after the measured voltage of the output of the battery falls below a threshold.
